(19) United States
(12) Patent Application Publication
(10) Pub. No.: US 2010/0289506 A1
(43) Pub. Date: Nov. 18, 2010

(54) CAPACITIVE SENSOR AND PROXIMITY DETECTOR USING IT

(76) Inventor: Anthony Moon, Llandaff, Cardiff (GB)

Correspondence Address: 3M INNOVATIVE PROPERTIES COMPANY, PO BOX 33427, ST. PAUL, MN, 55133-3427, US

(21) Appl. No.: 12/679,557

(22) PCT Filed: Sep. 24, 2008
(86) PCT No.: PCT/US08/77534

§ 371 Date: Jun. 28, 2010

(30) Foreign Application Priority Data
Sep. 25, 2007 (GB) 0718677.8

(51) Int. Cl. G01R 27/26

(52) U.S. Cl. 324/681

(57) ABSTRACT

A capacitive sensor may be used as a proximity detector in an obstruction warning system for road vehicles, e.g. for use when the vehicle is reversing. A digital signal processor 11 sends a sine wave through a sensor RC circuit 1, 7. A sensor plate 3 acts as one plate of a sensor capacitor 1 and the obstruction 45 acts as the other plate 5. Changes in the distance between the car 43 and the obstruction 45 result in changes in the capacitance of the sensor capacitor 1, changing the amplitude and phase of the sine wave output by the sensor RC circuit 1, 7. A reference sine wave, generated by a reference signal circuit 17, 19, 21 is subtracted from the sensor output signal in a subtractor 15. The reference signal has a phase offset from the sensor signal so that the amplitude of the difference signal is highly sensitive to changes in phase of the sensor signal. An additional signal, substantially identical to the sensor signal, is coupled to the output of the sensor RC circuit by a coupling capacitor 41. This provides a path to ground for high frequency noise without disrupting the sensor signal.

### CROSS-REFERENCE TO RELATED APPLICATION

This application claims priority to Great Britain Patent Application No. 0718677.8, filed Sep. 25, 2007, the disclosure of which is incorporated by reference herein in its entirety.

### TECHNICAL FIELD

The present invention relates to a sensor arrangement which detects changes in a capacitance, and to a proximity detector which uses the sensing arrangement. It may be used, for example, for detecting obstructions while maneuvering a vehicle, typically as part of a system to warn the driver of a road vehicle when the vehicle approaches an obstacle while reversing.

A capacitive sensor arrangement can be configured so that an alternating signal, such as a sine wave or a square wave, is input to a resistance-capacitance (RC) network (for example, a resistor in series with a signal path followed by a connection to a capacitor branching off the signal path). Changes to the capacitance in the RC network will change the amplitude (and possibly phase) of a signal at its output, and accordingly such capacitance changes can be monitored. In practice, various filters and buffer amplifiers may also be needed.

### BACKGROUND

Capacitive sensors used as proximity sensors in obstruction detection systems for vehicles are known e.g. from WO 02/19524, EP 1720254, WO 2004/054105 and WO 2005/012037, which are hereby incorporated by reference into the present application. In these arrangements, an alternating square wave signal is input to an RC (resistance-capacitance) network which includes the capacitance between a sensor plate (typically mounted on or in a vehicle rear bumper) and the ground. The RC network converts the square wave into a substantially triangular wave. As the capacitance of the sensor capacitor formed by the sensor plate increases, e.g. owing to the vehicle's approach to an obstruction, the amplitude of the substantially triangular wave reduces, and this amplitude variation is used to detect the capacitance changes and thus the approach to an obstruction. As discussed in WO 2004/054105, the way in which the sensor signal varies as the vehicle moves may be monitored, enabling a judgment to be made concerning the distance between the vehicle and the obstruction even though different obstructions, made of different materials, will have different effects on the capacitance of the sensor arrangement. The movement of the vehicle may be monitored by detecting movement of the wheels or of some convenient part of the power train.

### SUMMARY

It may be necessary to detect small changes in the capacitance. This is particularly the case for a vehicle-mounted obstruction detector. Accordingly, in one aspect of the present invention a signal is provided having the same frequency as a signal applied to the RC network and this signal is added to or subtracted from a signal obtained from the output of the RC network (preferably after buffering). The resultant sum or difference signal is used in the detection of changes in the capacitance of the RC network. Preferably the additional signal has substantially the same waveform shape as the signal with which it is added or subtracted, and preferably they are both sine waves.

The sum or difference signal may make it easier to detect small changes in the capacitance. For example, when two sine waves are added or subtracted the resultant signal is also a sine wave. The phase of the resultant signal either will be at or will be 90° offset from a phase between the respective phases of the two signals which were combined. The amplitude of the resultant signal will depend both on the respective amplitudes of the two input signals and also on the sine or cosine of the difference between the phases. As the capacitance of the RC network changes, both the phase and the amplitude of the signal output from the network will change. When this happens, the amplitude of the sum or difference signal will be affected by both the change in amplitude of the signal output from the RC network and the change in the phase of this signal. It is possible to arrange the overall phase difference between the signals being added or subtracted so that small changes in the phase difference have a large effect on the amplitude of the sum or difference signal. In this way, the amplitude of the sum or difference signal can be made to be very sensitive to changes in the sensor capacitance.

Preferably the reference signal, which is added or subtracted with the signal obtained from the RC network, is generated by passing the same input signal through a second RC network having the same time constant as the RC network including the sensor capacitance. Preferably the RC network for the reference signal has a much greater capacitance and much smaller resistance than the RC network for the sensor signal, so that the reference signal is more robust and is less affected by small capacitance variations and by radio frequency interference. This arrangement, of generating the reference signal from the same input signal using the second RC network, can be implemented with relatively few circuit components and has the advantage that the reference signal will always have exactly the same average frequency as the signal output from the sensor RC network, and the reference signal will track any slight amplitude, frequency or phase variations in the input signal, so that the sum or difference signal is not influenced by any slight instabilities or variations in the performance of the circuitry used to generate the input signal.

As an alternative, the reference signal could be generated independently from the signal supplied to the sensor RC network. For example, the signal input to the sensor RC network could be generated by a digital signal processor, and the reference signal could be generated using a reference RC network as described above, receiving a matching signal generated by the same digital signal processor. This arrangement has the advantage that the software controlling the digital signal processor can be used to set a phase difference between the signal input to the sensor RC network and the signal input to the reference RC network so as to obtain the desired phase relationship between the reference signal and the signal obtained from the output of the sensor RC network, taking into account any phase shift introduced by components such as a buffer amplifier provided between the sensor RC network and the circuit that performs the addition or subtraction. If both RC networks receive the same input signal, it may be necessary to provide a phase shifting circuit (preferably at the output of the reference RC network) in order to provide the desired phase relationship.

Although it is preferred to use a sine wave as the input signal, other signals are possible. For example, the input signal may be a square wave. In this case the output from the RC network will be substantially a triangle wave. In this case, the variations in the sensor capacitance do not change the phase of the output signal, but only its amplitude. The reference signal would be adjusted to have the same phase as the signal obtained from the RC network including the sensor capacitor, and one signal would be subtracted from the other. An amplified difference signal, obtained for example by providing the two signals to the inputs of a difference amplifier, would have a high sensitivity to changes in the sensor capacitance.

According to a second aspect of the present invention, which may be provided in combination with the first aspect or separately, a signal having approximately the same waveform, amplitude and phase as the signal output from the sensor RC network is capacitively coupled to the output of the sensor RC network and is also capacitively coupled, in parallel with the first capacitive coupling, to ground (in this context, the term “ground” covers any fixed voltage). In so far as this additional signal is the same as the signal output by the sensor RC network, there is no voltage drop across the capacitive coupling between the two signals and no current flows through it. However, in some circumstances the sensor capacitance can be prone to noise. For example, in the case of an obstruction detector system for vehicles, the sensor capacitance may be provided by an electrical conductor which is of substantial size (e.g. the entire width of a vehicle bumper), and it may tend to pick up radio frequency noise. On the other hand, the arrangement for generating the additional signal can be configured so as to make it much less sensitive to such noise. Consequently, such high frequency noise appearing at the output of the sensor RC network is effectively grounded through the two capacitive couplings in series.

In principle, if the additional signal is exactly the same as the sensor signal, this arrangement has no effect on the sensor operation other than to remove high frequency noise. In practice, small differences in phase and amplitude between the two signals can be tolerated, but this will tend to reduce the sensitivity of the system to changes in the sensor capacitance. Accordingly, the additional signal can be generated using an RC network having the same time constant as the sensor RC network and receiving the same input signal. In this case, the additional signal is coupled to ground through the capacitance of the RC network used to generate it. This provides a simple and effective means of generating the additional signal, but has the consequence that the additional signal will not vary with changes in the sensor capacitance, and so some differences in phase and amplitude between the two signals will arise. Such phase and amplitude differences can be reduced by generating the additional signal from the signal output by the sensor RC network. However, this would require the provision of additional circuitry such as a phase locked loop in order to ensure that the additional signal tracked changes in phase of the signal output by the sensor RC network, and this would add to overall complexity and cost of the system.

In the case where the input waveform is a sine wave, so that the sensor RC network only changes the phase and amplitude of the signal and not the shape of its waveform, the additional signal could be generated by a circuit that receives the same input signal and attenuates it preceded or followed by a phase shifter circuit, so as to mimic the phase and amplitude effects of the sensor RC network.

As with the first aspect of the invention, the additional signal may be generated separately from the signal provided to the sensor RC network. For example, they may both be generated by a digital signal processor.

This aspect of the present invention can be used with sine wave signals but is not limited to them. For example, the signal input to the sensor RC network may be a square wave so that the sensor output signal is substantially a triangular wave.

Although the discussion above has referred to an RC (resistance-capacitance) network including the sensor capacitance, it would in principle be possible to use an LC (inductance-capacitance) network or an LRC (inductance-resistance-capacitance) network. It is merely necessary that the change in the sensor capacitance alters the phase and/or amplitude of the signal output from the network. However, for reasons of cost and manufacturing convenience, it is preferred to avoid the use of inductors.

Embodiments of the present invention, given by way of non-limiting example, will now be described with reference to the following drawings.

### BRIEF DESCRIPTION OF DRAWINGS

FIG. 1 shows the arrangement of a capacitive sensor according to a first embodiment of the present invention.

FIG. 2 illustrates the changes in the effect of an RC circuit on an input sine wave as the capacitance in the RC circuit changes.

FIG. 3 is a circuit diagram of an example of a phase shifter circuit.

FIG. 4 shows waveforms for combining digital outputs into a pseudo sine wave.

FIG. 5 shows a capacitive sensor arrangement according to a second embodiment of the present invention.

FIG. 6 shows a capacitive sensor arrangement according to a third embodiment of the present invention.

FIG. 7 shows an obstruction and the rear part of a car fitted with an obstruction warning system.

FIG. 8 is a schematic block diagram of an obstruction warning system for a road vehicle.

FIG. 9 shows schematically the location of a sensor plate of a capacitive sensor within the rear bumper of a road vehicle.

### DETAILED DESCRIPTION

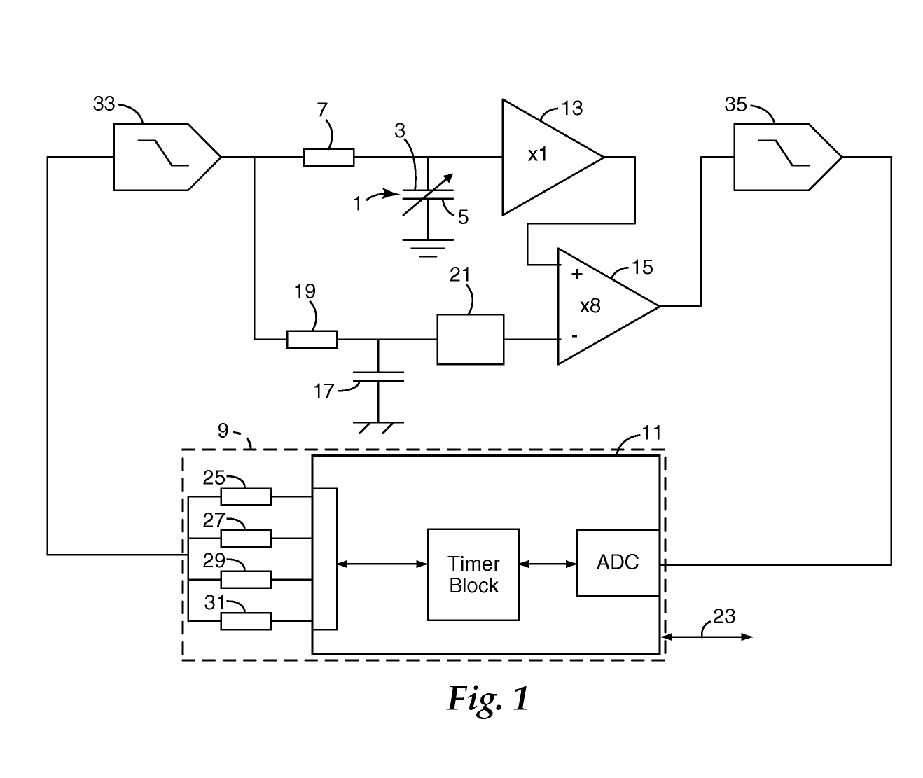

FIG. 1 shows a capacitive sensor according to a first embodiment of the present invention. The sensor is arranged to detect changes in the capacitance of a sensor capacitor 1. The sensor of FIG. 1 might be used, for example, in a proximity sensor, e.g. as part of a parking aid fitted to a road vehicle in order to give a warning when the vehicle approaches an obstruction while reversing. In such an arrangement, the sensor is configured so that the capacitance of the sensor capacitor 1 varies as the distance to an external object changes. In this case, the sensor itself will typically only include one plate 3 of the sensor capacitor 1, connected to the remainder of the sensor, and the other plate 5 will be provided by the ground behind the vehicle together with any nearby obstacle.

In the sensor of FIG. 1 the sensor capacitor 1 is connected to a sensor resistor 7 to form a sensor RC circuit. The resistance of the sensor resistor 7 is chosen so that, in combination with the rest capacitance of the sensor capacitor 1, the RC circuit has a suitable time constant. In order to detect changes in the capacitance of the sensor capacitor 1, a control system 9 passes an AC signal through the sensor RC circuit formed by the sensor capacitor 1 and the sensor resistor 7, and detects changes in the capacitance of the sensor capacitor 1 from changes in the way in which the RC circuit alters the signal. It is usually preferred for the period of the AC signal to be of the same order of magnitude as the time constant of the sensor RC circuit, for best circuit operation.

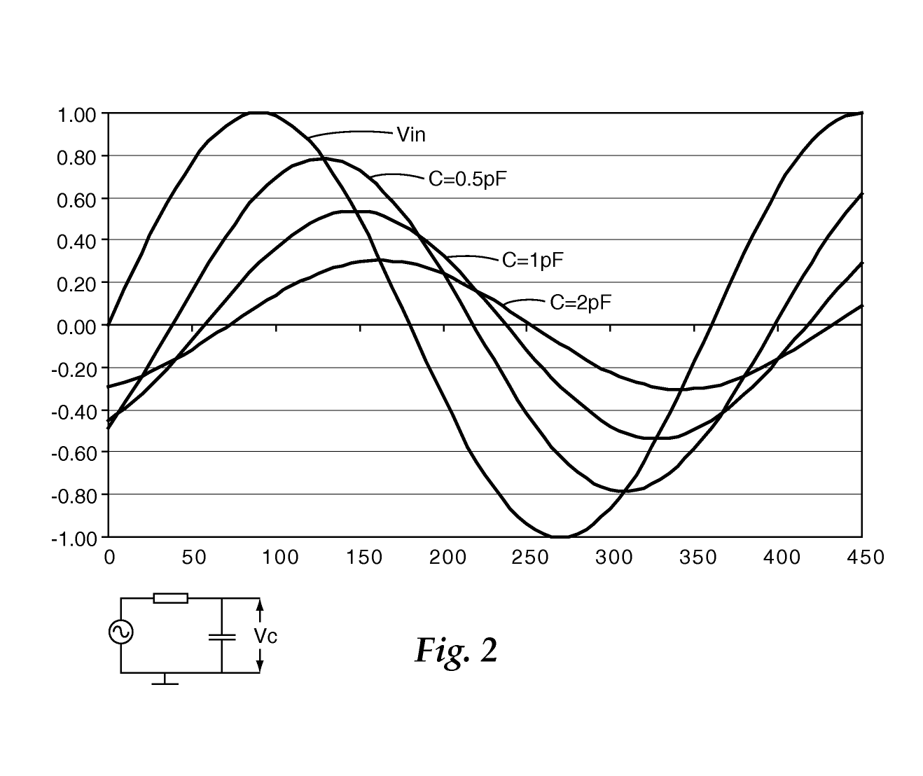

As shown in FIG. 1, the control system 9 may comprise a digital signal processor 11, although it is not essential and other ways of making a suitable control system will be apparent to those skilled in the art. In the embodiment of FIG. 1, the AC signal is a sine wave, although other waveforms are possible and the use of a square wave (which is converted by the RC circuit into a substantially triangular wave) will be discussed later. As shown in FIG. 2, when a sine wave is passed through an RC circuit, both the phase and the amplitude of the wave are altered. The amount of these changes depends on the time constant of the RC circuit. Changes in the sensor capacitor 1 will create corresponding changes in the time constant of the sensor RC circuit, and therefore changes in the capacitance of the sensor capacitor 1 result in changes in the output signal from the RC circuit. This is illustrated in FIG. 2, where output waveforms for three different capacitor values are given for a constant input signal.

FIG. 2 shows a frequency of 25 kHz for the AC signal. This frequency is suitable for use in a vehicle obstruction detector because it is slightly higher than the range of audible frequencies (which are typically in the range of 20 Hz to 20 kHz), so that if the signal is picked up as noise in a vehicle audio device such as a radio, the noise is inaudible. Consequently, at least in applications such as a vehicle parking sensor, signal frequencies above 20 kHz are preferred. However, it is also preferred that the frequency should normally be below about 100 kHz so that any high frequency noise (e.g. radio signal noise) picked up by the sensor can be filtered out without significantly affecting the operation of the sensor, and also so that the sensor itself does not generate radio frequency noise.

In a proximity sensor for a vehicle parking aid, the rest capacitance of the sensor capacitor 1 (i.e. the capacitance between the plate 3 and ground in the absence of any obstruction) might typically be in the range 0.2 pF to 5 pF, more typically at least 0.5 pF and generally no more than 2 pF, for example, somewhere between 0.8 and 0.9 pF. These low capacitance values are used in order to enable the proximity sensor to detect objects at a useful distance. If a vehicle parking aid is to be of any practical help, its proximity sensor needs to be able to detect objects at a range of well over 0.1 metres (preferably at least 0.5 metres for a small obstruction and more than 1 metre for a larger one). In this case, the sensor resistor 7 might have a value in the range of 2 to 50 MΩ, for example at least 5 MΩ and typically no more than 20 MΩ, for example about 10 MΩ Accordingly, the time constant of the RC circuit, in a sensor for use in a parking aid, might typically be in the range of 2 to 50 μs, preferably at least 5 μs and also preferably no more than 20 μs. Values around 10 μs, or perhaps slightly less (perhaps 8 to 9 μs) are likely to be suitable.

Because of the low value of the sensor capacitor 1 and the high value of the sensor resistor 7, the output of the sensor RC circuit is buffered by a buffer amplifier 13. Preferably, this amplifier is constructed with feedback so as to increase the effective impedance of the resistive element of the sensor RC circuit. This in turn reduces the actual values of the physical resistors required to construct the sensor resistor 7, making the circuit easier to construct.

In practice, the sensor may need to detect relatively small changes in the capacitance of the sensor capacitor 1. For example, when the sensor is being used as a proximity sensor in a vehicle parking aid, with a rest capacitance for the sensor capacitor of about 0.85 pF, the sensor should preferably be able to detect capacitance changes of only about 15 fF to 20 fF (i.e. in the region of 2% of the rest capacitance). Consequently, the change in phase and amplitude of the sine wave signal, caused by the change in capacitance, may be very small, and difficult for the control system 9 to detect. In order to avoid the need for expensive components in the control system 9, such as a high resolution, fast analogue-to-digital converter in the digital signal processor 11, an arrangement is provided in the capacitive sensor of FIG. 1 to pre-process the signal output by the buffer amplifier 13 so as to generate a signal, for input to the control system 9, in which the changes in the capacitance of the sensor capacity 1 are more easily detectable.

In this arrangement, a reference signal is generated having approximately the same amplitude as a signal output from the buffer amplifier 13, and this is combined with the signal from the buffer amplifier 13 in a signal subtractor 15. The reference signal is not influenced by changes in the capacitance of the sensor capacitor 1, and has a substantially constant amplitude and phase. Preferably, the reference signal is arranged to have a slight phase offset from the phase of the signal output by the buffer amplifier 13. This phase offset is normally arranged to be less than 30°.

The effect of subtracting one sine wave from another, where the sine waves have the same amplitude and have a phase difference θ, is shown in the following equation.

$$sin ( t ) - sin ( t - θ ) = 2 sin ( \frac{θ}{2} ) cos ( t - \frac{θ}{2} )$$

It can be seen that the phase of the output difference signal is 90° ahead (because it is a cosine function) of a phase midway between the phases of the two input signals, and that the amplitude of the output difference signal is multiplied by the sine of half the phase difference θ.

When the capacitance of the sensor capacitor 1 changes, this creates a small change in both the amplitude and phase of the signal output from the buffer amplifier 13. The change in amplitude will have an effect on the amplitude of the signal output by the subtractor 15, but the change due to this factor will remain small. It will also create a small change in the phase of the signal output by the subtractor 15. More importantly, the change in phase of the signal from the buffer amplifier 13 implies a corresponding change in the phase difference θ between the two signals input to the subtractor 15, since the phase of the reference signal does not change. This creates only a small change in the phase of the output of the subtractor 15, because the phase of the signal output by the subtractor 15 is a function of half the phase difference between the two input signals, as shown in the formula set out above, so that the change in phase of the signal output from the subtractor 15 is even less than the change in phase of the signal output from the buffer amplifier 13. However, as shown in the formula above, the amplitude of the signal output by the subtractor 15 is multiplied by sin(θ/2). If the value of the phase difference θ is chosen so that the slope of sin(θ/2) is steep (i.e. θ is reasonably close to 0°), small changes in θ will nevertheless result in large changes in the amplitude of the signal output by the subtractor 15.

In this way, the subtraction of the reference signal from the signal output by the buffer amplifier 13 is used to create a signal which has a large change in amplitude in response to only a small change in the capacitance of the sensor capacitor 1. However, the slope of a sine wave is steepest at the points where the waveform crosses zero, with the consequence that if the phase offset θ is close to zero, the amplitude of the difference signal is very small. Accordingly, the value of θ is selected so as to be sufficiently far from zero that the multiplication factor sin(θ/2) does not reduce the total signal amplitude to an unusably low level, while nevertheless having a steep enough slope that the small changes in θ caused by changes in the sensor capacitor 1 result in large changes in the amplitude of the difference signal. Accordingly, θ is preferably at least 10° (so that a sin(θ/2) is not substantially less than 0.1). Additionally, in order to compensate for the low level of the difference signal created according to the formula set out above, and taking into account the loss of signal amplitude in the sensor RC circuit, the subtractor 15 preferably also has an amplifying function. In FIG. 1 a gain of 8 is shown for the subtractor 15. The actual value selected will depend on the performance of the input circuits of the control system 9, but normally a gain of between 5 and 20 will be suitable.

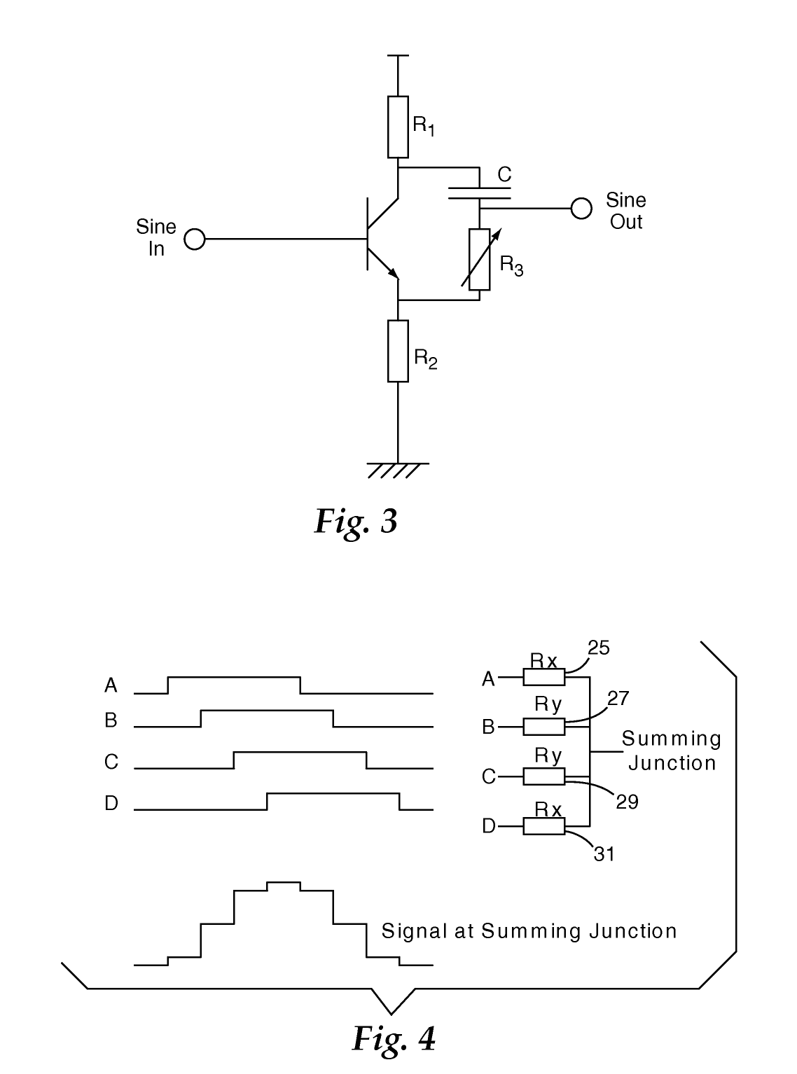

In order to generate the reference signal, for input to the subtractor 15, a reference RC circuit, made up of reference capacitor 17 and reference resistor 19, is connected in parallel to the sensor RC circuit of sensor capacitor 1 and sensor resistor 7, so as to receive the same input sine wave signal. The reference RC circuit is arranged to have substantially the same time constant as the sensor RC circuit, so that its output signal is substantially the same as the signal output by the sensor RC circuit. However, the reference RC circuit is preferably constructed using a much larger capacitor and a much smaller resistor than the sensor RC circuit. For example, the reference capacitor 17 may have a capacitance of the order of 1 nF and the reference resistor 19 may have a resistance of approximately 10 kΩ, that is to say the reference capacitor is about a thousand times the value of the sensor capacitor and the reference resistor is about one thousandth of the resistance of the sensor resistor. Consequently, the signal output by the reference RC circuit is much more robust than the signal output by the sensor RC circuit, and so the reference RC circuit does not need a buffer amplifier equivalent to the amplifier 13. A phase shifter 21 is provided between the reference RC circuit and the input to the subtractor 15 so as to adjust the phase of the reference signal in view of any phase shift introduced to the sensor signal by feedback in the buffer amplifier 13 and in order to provide the desired level of phase offset θ between the two signals input to the subtractor 15. Many possible ways of constructing the phase shifter 21 will be apparent to those skilled in the art. A simple active phase shift circuit is shown in FIG. 3, but use of this particular circuit is not essential and any suitable phase shifting arrangement may be used.

As an alternative to subtracting the reference signal from the sensor signal, the phase offset could be altered by 180° (in effect inverting the reference signal) and the signals could be added. The effect of summing the signals is shown by the following equation.

$$sin ( t ) + sin ( t - θ ) = 2 cos ( \frac{θ}{2} ) sin ( t - \frac{θ}{2} )$$

In this case, the amplitude of the output signal depends on cos(θ/2) and θ should be chosen so that the slope of cos(θ/2) is steep (i.e. θ is reasonably close to)180°.

As shown in FIG. 1, the control system 9 includes a digital signal processor 11. Preferably, the digital signal processor is of the type having an analogue-to-digital converter (shown as ADC in FIG. 1) the output of which can be written directly into memory without interrupting the main processor unit of the digital signal processor. This frees up the processor unit for performing digital signal processing functions such as digital filtering and correlation. The digital signal processor is programmed so that a timer block generates a fixed frequency waveform (or alternatively a plurality of waveforms suitable for combination into the desired signal waveform), to be output from the digital signal processor and applied to the sensor RC circuit, following filtering if appropriate. The timer block also triggers the operation of the analogue-to-digital converter, so that the waveform received by the control system 9 is sampled precisely in synchronisation with the generated waveform. The digital signal processor 11 analyses the incoming waveform, after it has been digitised, and uses the absolute amplitude and/or changes in amplitude (and possibly also phase) to sense the capacitance of the sensor capacitor 1 and/or changes in the capacitance, and outputs a signal representative of the level of capacitance and/or changes therein via a connection 23 for communication between the sensor of FIG. 1 and external apparatus. For example, the digital signal processor 11 may use lock-in amplifier techniques to measure the precise phase and amplitude difference between the signal received from the subtractor 15 and a theoretical or actual reference signal which is locked in phase and frequency with the waveform generated by the digital signal processor 11 for supply to the sensor RC circuit.

In the arrangement shown in FIG. 1, the digital signal processor 11 is programmed to provide four signal outputs on four separate output lines, which are combined to form a pseudo sine wave. The generation of the pseudo sine wave is shown in more detail in FIG. 4. As shown in FIG. 4, the signal provided on each output line can be a simple digital signal, having a 50% duty ratio. Signals on successive outputs are each delayed by one eighth of the duty period compared with the signal on the preceding output line. As shown in FIGS. 1 and 4, each output line is connected through a respective resistor 25, 27, 29, 31 to a summing junction. As shown in FIG. 4, resistor 25 connected to the output having the signal first to go high and resistor 31 connected to the output having the signal last to go high, both have the same value R. The other two resistors 27, 29 also have a common value R_{y}, which is different from R. Analogue addition of the signal values takes place at the summing junction, and each signal is weighted by the value (Rₓ or R_{y}) of its associated resistor, so as to generate a multi-level step-like waveform as shown in the lower part of FIG. 4. By selecting suitable values for Rₓ and R_{y}, so as to adjust the relative heights of the different steps, a pseudo sine wave can be generated at the summing junction.

The step-like multi-value waveform is smoothed by a low pass filter 33 (for example an active Butterworth filter) which is arranged to pass the main pseudo sine wave frequency while blocking any harmonics. This generates a sine wave which is sufficiently pure to be provided to the sensor RC circuit.

Alternative arrangements may be used, if desired, to generate the sine wave to be supplied to the sensor RC circuit, and the arrangement discussed with reference to FIG. 4 is provided merely as an example of one simple way of generating an appropriate signal. If it is desired to input some other waveform to the RC circuit, instead of a sine wave, the signal generating arrangements will need to be modified accordingly. For example, in order to generate a square wave a single digital output from the digital signal processor 11 can be used, and there is no need for a summing junction or the low pass filter 33.

A further low pass filter 35, with a cut-off frequency selected in accordance with the sample rate of the analogue-to-digital converter at the input of the digital signal processor 11, is provided between the output of the subtractor 15 and the input to the control system 9 in order to avoid aliasing during operation of the analogue-to-digital converter.

The filters 33, 35, and other components in the circuitry shown in FIG. 1, are likely to introduce phase and amplitude shifts in the signal. However, these phase and amplitude shifts will be substantially constant except for the changes created by the changes in the capacitance of the sensor capacitor 1, and therefore they do not interfere with the ability of the digital signal processor 11 to detect and measure changes in the signal resulting from changes in the capacitance of the sensor capacitor 1.

The control system 9 may also be arranged to respond to inputs received over the external connection 23, which may for example start or stop sensor operation. When the sensor of FIG. 1 is being used in a vehicle parking aid to detect obstructions behind a vehicle, it is usually more important for the parking aid to respond to changes in capacitance of the sensor capacitor 1 than to use the absolute capacitance value. Accordingly, the system may be set up to send the signal to the capacitive sensor of FIG. 1 when the vehicle is initially placed in reverse gear and the digital signal processor 11 may be programmed to respond to this input by beginning sensor operation and measuring the capacitance at that time. Subsequently, for as long as reverse gear is engaged, the sensor circuit may continue to operate and provide information about changes in capacitance after the initial measurement. Alternatively, the control system 9 of FIG. 1 may simply output a signal corresponding to the absolute value of the sensor capacitor 1 throughout the period of operation of the sensor, and the remaining circuitry in the parking aid may be arranged to monitor changes in the capacitance from the initial value received when reverse gear is engaged.

Various modifications are possible in the capacitive sensor of FIG. 1. For example, the phase shifter 21 may be placed before the reference resistor 19 instead of in the position shown. Other arrangements may be used to generate the reference signal input to the subtractor 15, in place of the reference RC circuit made up of the capacitor 17 and resistor 19. For example, the reference signal may be generated from a digital output (or combination of outputs) from the digital signal processor, in a similar way to the generation of the signal input to the sensor RC circuit. This would have the advantage that the phase of the reference signal could be controlled directly by the digital signal processor 11, and varied under software control, so that the phase shifter 21 would not be needed.

As mentioned above, other waveforms such as a square wave may be input to the sensor RC circuit instead of the sine wave discussed above. In the case of a square wave, the output from the sensor RC circuit is a substantially triangular wave, and variations in the capacitance of the sensor capacitor 1 affect the amplitude of the triangular wave but do not substantially affect its phase. Accordingly, in this case the purpose of the subtractor 15 is to provide an amplified version of the difference in signal amplitude between the two inputs, and the reference signal should be in phase with the signal from the buffer amplifier 13. Accordingly, the phase shifter 21 will only be needed if the buffer amplifier 13 introduces a phase shift. However, the use of a sine wave is preferred over the use of a square wave input to the RC circuit and a triangular wave output, because the reliance on amplitude rather than phase effects of changes of the capacitance of the sensor capacitor 1 mean that accurate amplification is necessary in the buffer amplifier 13 and a subtractor 15, and the sharp points of the triangle wave require the amplifiers to have a high bandwidth which makes the arrangement more susceptible to interference and noise. If a sine wave is used, higher frequencies can be filtered out. For example, the subtractor 15 can be configured as a differential amplifier having a bandwidth which excludes frequencies substantially higher than the frequency of the sine wave. In this way, any radio frequency noise picked up in the sensor capacitor 1 does not substantially affect the signal output from the subtractor 15.

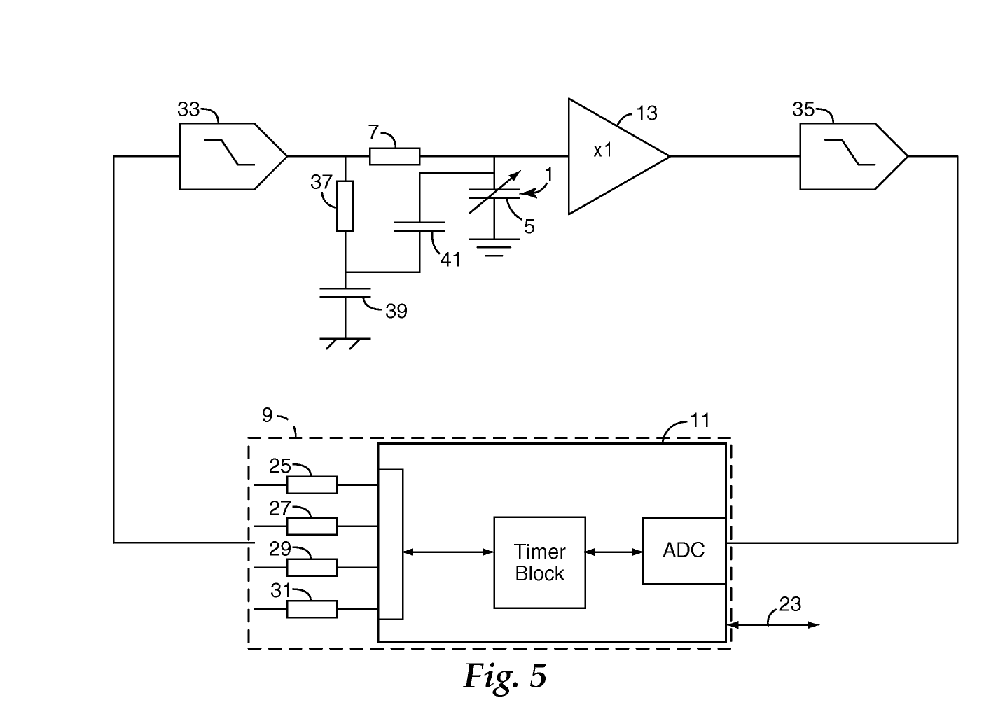

FIG. 5 shows a capacitive sensor according to a second embodiment of the present invention. Many of the parts of the sensor of FIG. 5 are the same as in the sensor of FIG. 1, and are given the same reference numerals. The description given above with reference to FIGS. 1 to 4 applies equally to the sensor of FIG. 5 except with respect to the parts of FIG. 5 that are different from FIG. 1.

In FIG. 5, the arrangement of adding or subtracting the signal from the buffer amplifier 13 with a reference signal is not used, and accordingly FIG. 5 does not contain the subtractor 15 or any arrangement, such as the reference capacitor 17, the reference resistor 19 and the phase shifter 21, for generating the reference signal.

As mentioned above, the signal input to the buffer amplifier 13 may be susceptible to high frequency noise, especially if the capacitance of the sensor capacitor 1 is very small and it has a large capacitor plate, as tends to be the case in a proximity sensor such as an obstruction sensor for a vehicle parking aid. In the capacitive sensor of FIG. 5, an arrangement is provided to remove at least some high frequency noise. Circuitry is provided to generate an additional “replica” signal which is capacitively coupled to the signal output by the sensor RC circuit made up of the sensor capacitor 1 and the sensor resistor 7. The additional signal is substantially the same as the sensor signal in terms of waveform, phase and amplitude (although in practice slight differences can be tolerated). However, the additional signal is arranged to be much less susceptible to noise than the sensor signal, and the circuitry is also arranged to provide a capacitive coupling between the additional signal and ground.

In the capacitive sensor of FIG. 5, the additional signal is generated by providing a further RC circuit, made up of an additional resistor 37 and an additional capacitor 39, connected to receive the same input signal as is provided to the sensor RC circuit. The additional RC circuit is arranged to have the same time constant as the sensor RC circuit, but, in a similar manner to the reference RC circuit of FIG. 1, the additional RC circuit of FIG. 5 uses a much greater capacitance and much smaller resistance to obtain that time constant, thereby providing a more robust signal which is less sensitive to noise.

The additional signal and the sensor signal are coupled by a coupling capacitor 41. In theory, if the additional signal and the sensor signal are absolutely identical, there will never be any voltage drop across the coupling capacitor 41 and so no current will flow through it, and it will have no effect on the sensor signal. However, the coupling capacitor 41 and the additional capacitor 39 provide a path to ground from the sensor signal at the input to the buffer amplifier 13, and this path can be arranged to have a low impedance for high frequency signals, since the additional capacitor 39 can have, for example, a capacitance a thousand times the capacitance of the sensor capacitor 1, and the coupling capacity 41 can also be chosen to have a similarly large capacitance. Accordingly, any high frequency noise appearing in the sensor signal, for example as a result of radio frequency signals picked up by the physically large plate 3 of the sensor capacitor 1, are effectively shunted to ground through the coupling capacitor 41 and the additional capacitor 39, and are not input to the buffer amplifier 13.

Except for the presence of the additional RC circuit and the coupling capacitor 41 and the omission of the reference RC circuit, phase shifter 21 and the subtractor 15, the capacitive sensor of FIG. 5 is substantially the same as the capacitive sensor of FIG. 1, and the description of FIG. 1 applies equally to FIG. 5.

In FIG. 5, the additional signal has been generated using the additional RC circuit made up of additional resistor 37 and additional capacitor 39. This is a simple and cost effective way of generating the additional signal, but it is not essential and alternative ways of generating the additional signal may be used. In the circuit shown in FIG. 5, the additional signal may need to have its phase and/or amplitude adjusted in order to match the sensor signal, for example in the case that the time constant of the additional RC circuit is not precisely the same as the time constant of the sensor RC circuit. Such adjustments can be achieved by using a phase shifter, similar to the phase shifter 21 of FIG. 1, and/or an amplifier, as necessary. These may be placed either before the additional resistor 37 or in the line from the additional RC circuit to the coupling capacitor 41. However, any circuitry placed in the line to the coupling capacitor 41 must have a low output impedance so that high frequency signals passing through the coupling capacitor 41 are shunted to ground. In this case, the high frequency noise may be shunted to ground through the internal circuits of the components placed in the line leading to the coupling capacitor 41, and not via the additional capacitor 39.

As in the case of the reference signal of FIG. 1, the additional signal of FIG. 5 may be generated from a separate output from the digital signal processor 11, and by suitable selection of signal amplitude and phase it may be possible to omit the additional RC circuit entirely in this case.

As with the capacitive sensor of FIG. 1, it is preferred to use a sine wave in the sensor of FIG. 5 but other waveforms such as a square wave signal may be used.

Since the additional signal and the sensor signal are nominally identical, and the only current flowing through the coupling capacitor 41 is the result of high frequency noise, the coupling capacitor 41 can in principle be replaced by a resistor, or alternatively a resistor may be placed in series or in parallel with coupling capacitor 41. Capacitive coupling is preferred because of the possibility of slight differences between the additional signal and the sensor signal. A capacitive coupling will have a lower impedance for high frequency noise than for the sensor signal, allowing the effect of the coupling on the sensor signal to be less than its effect on noise. Additionally, an inductor in series with the input to the buffer amplifier 13 will also tend to reduce the amount of high frequency noise entering the buffer amplifier 13.

The methods discussed above for generating the additional signal do not respond to changes in the capacitance of the sensor capacitor 1. Accordingly, the additional signal will not track changes in the sensor signal caused by changes in the capacitance of the sensor capacitor 1, and this will result in slight amplitude and phase differences between the additional signal and the sensor signal. Consequently, the coupling of the additional signal to the sensor signal slightly changes the sensor signal, reducing the sensitivity of the signal to changes in the capacitance of the sensor capacitor 1. As discussed above, the use of the coupling capacitor 41 in the line coupling the additional signal to the sensor signal gives the coupling a frequency-dependent impedance, so as to improve the trade off between high frequency noise in the signal and loss of sensitivity to changes in the sensor capacitance. In principle, it is possible to make the additional signal responsive to changes in the capacitance of the sensor capacitor 1 by generating the additional signal in a dedicated signal generator circuit which is controlled by a phase locked loop, which in turn receives the sensor signal as a phase control input. This would mean that the phase of the additional signal would track changes in the phase of the sensor signal, while the phase locked loop could be arranged not to respond to high frequency noise components in the sensor signal. However, such circuitry would be complex, and difficult and expensive to provide. Furthermore, unless the phase locked loop had a very high input impedance at the terminal that received the sensor signal, the overall effect might be to reduce the quality of the signal input to the buffer amplifier 13 rather than to increase it. For these reasons, simple arrangements for generating the additional signal, which do not respond to changes in the capacitance of the sensor capacitor 1, are currently preferred.

FIG. 5 shows the additional signal being coupled to the sensor signal before it is input to the buffer amplifier 13. It would be possible, as an alternative, to couple the additional signal to the sensor signal after the buffer amplifier 13, but this is not preferred because the arrangement used to generate the additional signal would in this case have to take into account the effect of the buffer amplifier 13 on the phase and amplitude of the sensor signal, which would both increase the cost and complexity of the arrangement for generating the additional signal and would also make it more difficult to ensure that the additional signal had the correct phase and amplitude.

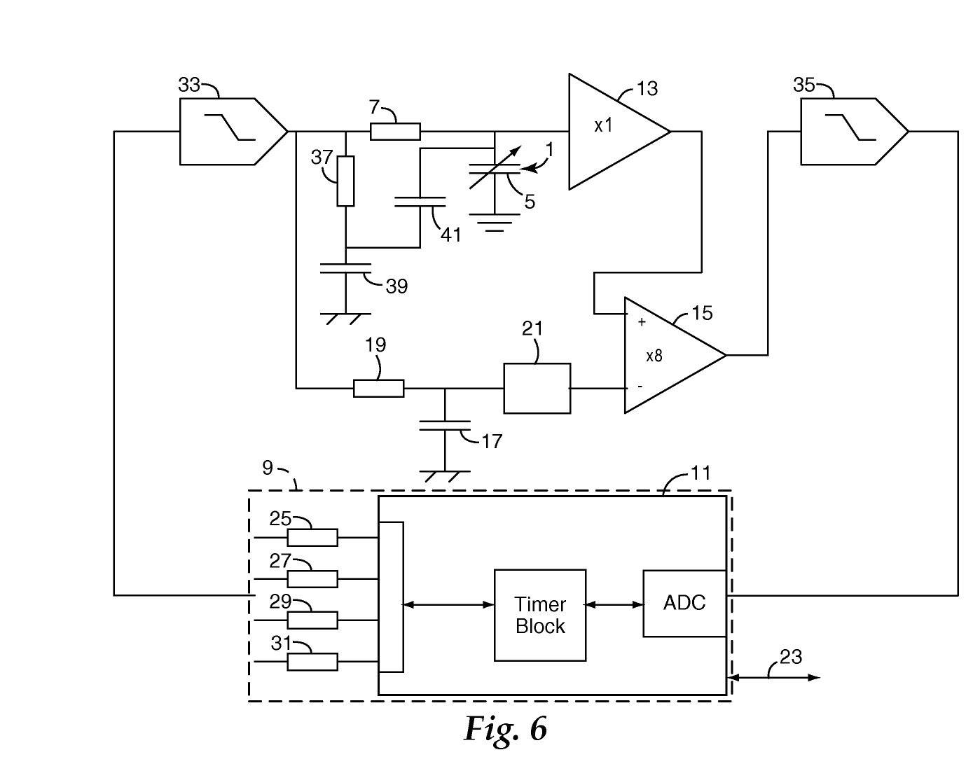

If desired, the arrangement of generating a reference signal and subtracting it from the sensor signal, as discussed with reference to FIG. 1, and the arrangement of generating an additional signal and coupling it to the sensor signal to reduce high frequency noise, as discussed with reference to FIG. 5, may both be used in the same capacitive sensor. Such an arrangement is shown in FIG. 6, which illustrates a capacitive sensor according to a third embodiment of the present invention. The various components shown in FIG. 6 function as discussed above with reference to FIGS. 1 and 5 and this discussion is not repeated here. Additionally, the capacitive sensor of FIG. 6 may be modified in the same ways as have been discussed with reference to FIGS. 1 and 5.

The embodiments shown in FIGS. 1, 5 and 6 are merely examples, and various modifications and alternatives are possible. For example, a different circuit arrangement may be used to generate either the reference signal or the additional signal, or both, from the AC waveform input to the sensor RC circuit, instead of using the RC circuit arrangements shown in the Figures. For example, in cases where the AC waveform is a sine wave so that the effect of the sensor RC circuit is only to change phase and amplitude, and not to change the shape of the waveform, the reference signal and/or the additional signal may be generated using a combination of an attenuation network, to alter the signal amplitude appropriately, and a phase shifter to adjust the phase of the signal appropriately. Additionally, if the digital signal processor 11 includes a digital-to-analogue converter, it may output the AC waveform for the sensor RC circuit, and/or the reference signal and/or the additional signal in the case that either or both of these signals are provided, from the digital signal processor directly in analogue form.

In the illustrated embodiments, the control system 9 uses a digital signal processor 11, but this is not essential. Analogue circuits may be used if desired, both for generating the signal to be applied to the sensor RC circuit and to detect changes in the amplitude and/or phase of the signal received from the sensor RC circuit.

In the illustrated embodiments, the signals are modified by being passed through an RC circuit comprising a single capacitor and a single resistor. Other RC circuit arrangements may be used. Additionally, an inductor may be used with or in place of the resistor. However, the use of an inductor is usually undesirable because the sensor capacitor 1 will normally have a very small capacitance, as discussed above, and consequently an inductor having a matched impedance would have to be unfeasibly large unless the capacitive sensor operated at a very high frequency.

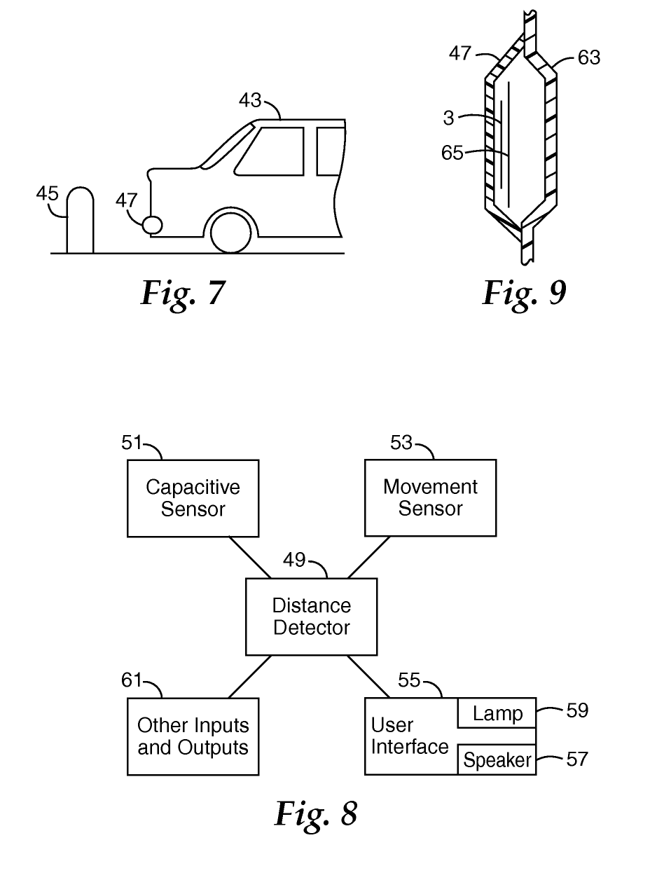

As previously mentioned, a capacitive sensor embodying the present invention may form part of an obstruction warning system for use in a vehicle, for example as an aid to reversing while parking FIG. 7 shows the rear part of a car and an obstruction behind the car. If the driver wishes to reverse the car 43, it may be difficult to judge the distance between the car and the obstruction 45. Additionally, if the obstruction 45 is relatively low, as shown in FIG. 7, it will disappear from the driver's field of view as the car 43 approaches it. In order to assist the driver, a capacitive sensor is arranged with a plate 3 of the sensor capacitor 1 formed by a large metallic strip (or a series of strips) mounted for example within the rear bumper 47 of the car 43. This metallic strip is capacitively coupled to the obstruction 45, which acts as the other plate 5 of the sensor capacitor 1. As the car 43 approaches the obstruction 45, the capacitance of the sensor capacitor 1 will change, and this is used by the obstruction detector system to determine the distance between the car 43 and obstruction 45, and issue warnings to the driver as the car 43 approaches the obstruction 45.

A schematic of an obstruction detection system is shown in FIG. 8. A distance detection module 49 controls the capacitive sensor 51 and receives signals from it indicating how the capacitance of the sensor capacitor is changing. The capacitive sensor 51 may be as shown in FIG. 1, FIG. 5 or FIG. 6. The distance detection module 49 also controls a movement sensor 53, and receives signals from it indicating the movement of the car. For example, the movement sensor 53 may detect rotation of the wheels, or corresponding movement in some other part of the vehicle transmission system. The distance detection module 49 monitors the way in which the capacitance of the capacitive sensor changes as the car 43 moves, and uses this to determine the distance between the car 43 and the obstruction 45. The use of movement data in combination with capacitive sensor data is discussed in more detail in, for example, WO 2004/054105. This information is used to provide a warning to a driver via a user interface 55. Typically, a warning sound (or a predefined announcement) will be provided from a speaker 57 when certain predetermined distances between the car 43 and the obstruction 45 are reached. Additional or alternative alerts may be provided, for example using a lamp 59, or an analogue or digital distance display may be provided. The user interface 55 may also include inputs for controlling the distance detection module 49, for example there may be a switch to turn the obstruction warning system on or off. Additionally, the distance detection module 49 will normally be in communication with other inputs and outputs 61. Typically, a sensor associated with the gear system will send a signal to the distance detection module 49 when reverse gear is engaged or disengaged, and this is used to control the operation of the obstruction warning system so that it operates automatically whenever the car 43 is reversing, but does not operate when the car is in a forward gear. The response of the capacitive sensor 51 to an obstruction 45 will depend on factors such as the size and design of the sensor plate 3, and where it is mounted, and therefore the relationship between capacitance, movement and distance to the obstruction will normally be determined experimentally for each particular design of obstruction detection system.

FIG. 9 shows schematically the arrangement of the sensor plate of the capacitive sensor within the bumper 47 of the car 43. The sensor plate 3, which forms one plate of the sensor capacitor 1, is provided between the material of the bumper 47 and the body 63 of the car 43. The capacitive sensor works because capacitive coupling between the plate 3 and the obstruction 45 creates at least a part of the capacitance of the sensor capacitor 1, with the obstruction 45 acting as part of the other capacitor plate 5 of the sensor capacitor 1. However, as can be seen in FIG. 9, the sensor plate 3 is inevitably in close proximity with the car body 63, which typically will be metal. Capacitive coupling between the plate 3 and the car body 63 has two undesirable effects. First, any electrical noise picked up by the metal car body 63 will be strongly coupled into the sensor plate 3. Second, coupling between the sensor plate 3 and the car body 63 will provide a significant part of the total capacitance of the sensor capacitor 1, reducing the effect of the capacitive coupling to the obstruction 45 and thereby reducing the sensitivity of the proximity sensing effect of the capacitive sensor.

In order to minimise these effects of capacitive coupling between the sensor plate 3 and the car body 63, a guard plate 65 is provided between them. As shown in FIG. 9, the guard plate 65 typically extends over a greater area than the sensor plate 3, so as to shield the entire area of the sensor plate 3. If the guard plate 65 is connected to a substantially noise-free fixed voltage, it will shield the sensor plate 3 from any electrical noise picked up by the car body 63. However, the close coupling between the sensor plate 3 and the car body 63 is now replaced by a close coupling between the sensor plate 3 and the guard plate 65, which can operate to reduce the sensitivity of the capacitive sensor in the same way. In order to minimise this effect, it is preferred to apply a signal to the guard plate 65 which is substantially the same as the signal from the sensor plate 3. For example, the guard plate 65 may be connected to the output of the buffer amplifier 13. Multiple guard plates may be used, as discussed for example in WO 2005/012037. If the noise reduction arrangement of FIGS. 5 and 6 is being used, an additional plate, connected to the output of the additional RC circuit, may be provided between the sensor plate 3 and the guard plate 65. In this case, the capacitive coupling between the additional plate and the sensor plate 3 can be used as all or part of the coupling capacitor 41.

In practice, the sensor plate 3 and the guard plate 65 may be formed as part of a laminate structure, including appropriate insulation layers, which may be fixed (e.g. by adhesive) to either the inner surface of the rear bumper 47 or to the car body 63. Preferably, it is adhered to the material of the bumper 47, and spaced from the car body 63, to reduce coupling between the guard plate 65 and the car body 63.

The parts of the capacitive sensor other than the sensor plate 3, the guard plate 65 if used and any other external plates such as the additional plate discussed above, may be provided separately from the plate or plates. In this case the remaining parts may be provided as all or part of a unit which is attachable to, and preferably detachable from, the plate or plates, and such a unit embodies an aspect of the present invention.

Although the present invention has been described largely with reference to the example of an obstruction detector for a road vehicle, many other uses are possible. It will be clear from the discussion of the obstruction sensor above that a capacitive sensor embodying the present invention may be used in a proximity sensor, and this may have applications other than in a vehicle obstruction sensor. For example, proximity sensors embodying the present invention may be used in a moving object such as a robot arm, e.g. for controlling movement and preventing collisions, or in a detector for responding to moving objects such as a sensor for controlling an automatic door depending on the approach of people or objects. A capacitive sensor embodying the present invention may also be used for other purposes, such as detecting whether a space is occupied, for example sensors inside a vehicle (perhaps in the ceiling) may be used to determine whether each individual seat is occupied, e.g. for integration with sensors to detect whether the corresponding seat belt has been done up. A further possible use is as a touch sensor in which the capacitance of a sensor plate is altered when a person or object touches it either directly or through a thin insulator layer. Many other uses will be apparent to those skilled in the art, and these uses are provided as examples.

The illustrated embodiments, and the further features, modifications and alternatives discussed above, are provided by way of non-limiting example, and many further alternatives and modifications within the scope of the invention will be apparent to those skilled in the art.

1-47. (canceled)

48. A capacitive sensor comprising:
a sensor circuit including at least one plate of a sensor capacitor or a connection therefor;
control means for applying a first alternating signal to the sensor circuit such that the effect of the sensor circuit on the signal varies with the capacitance of the sensor capacitor, and
for receiving a sensor signal derived from an output of the sensor circuit and detecting a parameter of the received sensor signal that is influenced by the capacitance of the sensor capacitor,
signal providing means for providing a second alternating signal having the same frequency as the first alternating signal; and
combining means for combining, by addition or subtraction, the second alternating signal with a signal received from the sensor circuit to provide a combined signal,
the said control means being connected to receive the said combined signal, or a signal derived from it, as the said sensor signal.

49. A capacitive sensor according to claim 48 in which the first alternating signal is a sine wave.

50. A capacitive sensor according to claim 48 in which the second alternating signal has the same waveform shape as the signal received from the sensor circuit by the combining means.

51. A capacitive sensor according to claim 50 in which the second alternating signal has a phase offset compared with the signal received from the sensor circuit by the combining means.

52. A capacitive sensor according to claim 48 in which the signal providing means is connected to receive the first alternating signal and generate the second alternating signal therefrom.

53. A capacitive sensor according to claim 48 in which the sensor circuit comprises an RC circuit comprising a series-connected resistor followed by a branch to a plate of the sensor capacitor or a connection therefor.

54. A capacitive sensor according to claim 53 in which the signal providing means comprises an RC circuit comprising a series-connected resistor followed by a branch to a capacitor.

55. A capacitive sensor according to claim 54 in which the RC circuit of the signal providing means has the same time constant as the RC circuit of the sensor circuit in a predetermined reference state of the capacitive sensor.

56. A capacitive sensor according to claim 55 in which the capacitor of the RC circuit of the signal providing means has at least ten times the capacitance of the sensor capacitor in the said reference state of the capacitive sensor.

57. A capacitive sensor according to claim 56 in which the capacitor of the RC circuit of the signal providing means has at least a hundred times the capacitance of the sensor capacitor in the said reference state of the capacitive sensor.

58. A capacitive sensor according to claim 54 in which the signal providing means comprises a phase shifter before or after its said RC circuit.

59. A capacitive sensor according to claim 48 in which the combining means is arranged to amplify the sum or difference of the second alternating signal and the signal received from the sensor circuit.

60. A capacitive sensor according to claim 48 in which the combining means comprises a subtractor connected to subtract one of the second alternating signal and the signal received from the sensor circuit from the other.

61. A capacitive sensor according to claim 48, further comprising a buffer amplifier connected to buffer the signal from the sensor circuit before it is input to the combining means.

62. A capacitive sensor according to claim 48, further comprising:
a signal providing arrangement for providing a further alternating signal which is substantially the same as, and is substantially in phase with, a signal provided from the sensor circuit, and for providing a coupling to ground, for noise components at a frequency substantially higher than the frequency of the further alternating signal, from the further alternating signal; and
coupling means for coupling the further alternating signal to the said signal provided from the sensor circuit, thereby to provide a path to ground via the coupling of the signal providing means for noise components, in the signal provided from the sensor circuit, at a frequency substantially higher than the frequency of the further alternating signal.

63. (canceled)

64. (canceled)

65. A capacitive sensor according to claim 62 in which the sensor circuit comprises an RC circuit comprising a series-connected resistor followed by a branch to a plate of the sensor capacitor or a connection therefore, and in which the signal providing arrangement comprises an RC circuit comprising a series-connected resistor followed by a branch to a capacitor.

66. A capacitive sensor according to claim 65 in which the RC circuit of the signal providing arrangement has the same time constant as the RC circuit of the sensor circuit in a predetermined reference state of the capacitive sensor.

67. A capacitive sensor according to claim 66 in which the capacitor of the RC circuit of the signal providing arrangement has at least ten times the capacitance of the sensor capacitor in the said reference state of the capacitive sensor.

68. A capacitive sensor according to claim 63 in which the signal providing arrangement is connected to receive the first alternating signal and generate the further alternating signal therefrom.

69. A capacitive sensor according to claim 63 in which the said coupling to ground of the signal providing means comprises a capacitive coupling.

70. A capacitive sensor according to claim 63 comprising a buffer amplifier connected to buffer the signal provided from the sensor circuit after its coupling to the further alternating signal.

71. A capacitive sensing method comprising:
passing a first alternating signal through a sensor circuit including at least one plate of a sensor capacitor, such that the effect of the sensor circuit on the signal varies with the capacitance of the sensor capacitor;
detecting a parameter of a sensor signal derived from an output of the sensor circuit, which parameter is influenced by the capacitance of the sensor capacitor,
providing a second alternating signal having the same frequency as the first alternating signal; and
combining, by addition or subtraction, the second alternating signal with a signal received from the sensor circuit to provide a combined signal,
the said sensor signal used in the said detecting step being the said combined signal, or a signal derived from it.

72. The capacitive sensing method according to claim 71, further comprising:
providing a further alternating signal which is substantially the same as, and is substantially in phase with, a signal provided from the sensor circuit, and providing a coupling to ground, for noise components at a frequency substantially higher than the frequency of the further alternating signal, from the further alternating signal; and
coupling the further alternating signal to the said signal provided from the sensor circuit, thereby to provide a path to ground, via the said coupling from the further alternating signal to ground, for noise components, in the signal provided from the sensor circuit, at a frequency substantially higher than the frequency of the further alternating signal.

73. (canceled)
